(19) United States
(12) Patent Application Publication
(10) Pub. No.: US 2015/0064525 A1
(43) Pub. Date: Mar. 5, 2015

(54) SENSOR DEVICE FOR A BATTERY CELL OF AN ELECTRICAL ENERGY ACCUMULATOR, BATTERY CELL, METHOD FOR PRODUCING SAME AND METHOD FOR MONITORING SAME

(71) Applicants: Fabian Henrici, Stuttgart (DE); Jake Christensen, Mountain View, CA (US); Nalin Chaturvedi, Sunnyvale, CA (US)

(72) Inventors: Fabian Henrici, Stuttgart (DE); Jake Christensen, Mountain View, CA (US); Nalin Chaturvedi, Sunnyvale, CA (US)

(73) Assignee: ROBERT BOSCH GMBH, Stuttgart (DE)

(21) Appl. No.: 14/379,234

(22) PCT Filed: Jan. 22, 2013
(86) PCT No.: PCT/EP2013/051129

§ 371 Date: Aug. 15, 2014

(30) Foreign Application Priority Data
Feb. 17, 2012 (DE) 10 2012 202 433.6

(51) Int. Cl. H01M 10/48; H01M 10/058; G01R 31/36; H01M 10/0525

(52) U.S. Cl. CPC H01M 10/48; H01M 10/0525; H01M 10/058; G01R 31/3606; G01R 31/3658
USPC 429/90; 29/623.1; 324/426

(57) ABSTRACT

A sensor apparatus for a battery cell of an electrical energy reservoir is proposed. The battery cell has a housing inside which an anode electrode electrically connected to a first battery terminal, a cathode electrode electrically connected to a second battery terminal, and an electrolyte for ion conduction between the anode electrode and the cathode electrode are receivable or received. The sensor apparatus comprises a reference electrode that is locatable or located inside the housing of the battery cell in ionic contact with the electrolyte. The sensor apparatus also comprises a sensing device for sensing sensor data. The sensing device is locatable or located inside the housing.

### FIELD OF THE INVENTION

The present invention relates to a sensor apparatus for a battery cell of an electrical energy reservoir, to a battery cell for an electrical energy reservoir, to a method for manufacturing a battery cell of an electrical energy reservoir, and to a method for monitoring a battery cell of an electrical energy reservoir, for example for use in battery management systems in particular for electric vehicles and hybrid electric vehicles.

### BACKGROUND INFORMATION

The measurement of electrode potentials in batteries or electrical energy reservoirs is meaningful in terms of assessing a state of the electrical energy reservoir. German Published Patent Application No. 10 2009 058 893 describes a method for monitoring a battery charge state.

### SUMMARY

In light of the above, the present invention presents an improved sensor apparatus for a battery cell of an electrical energy reservoir, an improved battery cell for an electrical energy reservoir, an improved method for manufacturing a battery cell of an electrical energy reservoir, and an improved method for monitoring a battery cell of an electrical energy reservoir, in accordance with the main claims. Advantageous embodiments are evident from the respective dependent claims and from the description below.

The present invention creates a sensor apparatus for a battery cell of an electrical energy reservoir, the battery cell having a housing inside which an anode electrode electrically connected to a first battery terminal, a cathode electrode electrically connected to a second battery terminal, and an electrolyte for ion conduction between the anode electrode and the cathode electrode are receivable or received, the sensor apparatus having the following features:

a reference electrode that is locatable or located inside the housing of the battery cell in ionic contact with the electrolyte; and

a sensing device for sensing sensor data, the sensing device being locatable or located inside the housing, the sensing device having an anode terminal that is electrically connectable or connected to the first battery terminal inside the housing, a cathode terminal that is electrically connectable or connected to the second battery terminal inside the housing, and a reference terminal that is electrically connectable or connected to the reference electrode inside the housing.

The electrical energy reservoir can be a battery, a so-called battery pack, etc., for example for an electric vehicle or the like. The electrical energy reservoir can have a plurality of battery cells or cells, in particular in the form of galvanic or electrochemical secondary cells, as sub-units of the energy reservoir, the battery cells being capable of forming the electrical energy reservoir. Alternatively, the electrical energy reservoir can have a single battery cell. The housing of the battery cell can be or can become hermetically sealed. The first battery terminal has a contact segment locatable or located outside the housing or on an outer surface of the housing. The second battery terminal has a contact segment locatable or located outside the housing or on an outer surface of the housing. An electrical connection from outside the battery cell to the battery cell can be created via the battery terminals or via the contact segments thereof. The anode electrode can be connectable or connected, for example by way of a first electrical lead, to the first battery terminal. The cathode electrode can be connectable or connected, for example by way of a second electrical lead, to the second battery terminal. The anode electrode, the cathode electrode, and the reference electrode can be locatable or located in contact with an electrolyte. The reference electrode has no electrical contact with the anode and cathode. The reference electrode can be embodied as a thin film or network. The sensing device can be at least one sensor element, a sensor, or the like for sensing at least one state variable of the battery cell.

The present invention furthermore creates a battery cell for an electrical energy reservoir, the battery cell having the following features:

an anode electrode that is electrically connectable or connected to a first battery terminal of the battery cell;

a cathode electrode that is electrically connectable or connected to a second battery terminal of the battery cell;

an electrolyte for ion conduction between the anode electrode and the cathode electrode inside the battery cell;

a housing inside which the anode electrode, the cathode electrode, and the electrolyte are receivable or received; and

a sensor apparatus, recited above, that is locatable or located inside the housing of the battery cell.

A sensor apparatus recited above can advantageously be utilized or used in connection with the battery cell in order to sense, in the interior of the battery cell, sensor data regarding at least one state variable of the cell.

The present invention further creates a method for manufacturing a battery cell of an electrical energy reservoir, the method having the following steps:

furnishing a basic unit of the battery cell, the basic unit having an anode electrode electrically connected to a first battery terminal, a cathode electrode electrically connected to a second battery terminal, and an electrolyte for ion conduction between the anode electrode and the cathode electrode, a reference electrode, and a sensing device for sensing sensor data;

locating the reference electrode in ionic contact with the electrolyte; and

connecting the sensing device, an anode terminal thereof being electrically connected to the first battery terminal, a cathode terminal thereof being electrically connected to the second battery terminal, and a reference terminal thereof being electrically connected to the reference electrode; and

enclosing the basic unit, the reference electrode, and the sensing device using a housing, only the first battery terminal and the second battery terminal being guided out of the housing.

An advantageous sensor apparatus recited above can be manufactured by executing the manufacturing method. In the enclosing step, a hermetically sealed housing having the battery terminals as external contacts can be formed.

The present invention furthermore creates a method for monitoring a battery cell of an electrical energy reservoir, the method having the following steps:

furnishing a battery cell that has an anode electrode that is electrically connected to a first battery terminal of the battery cell, a cathode electrode that is electrically connected to a second battery terminal of the battery cell, an electrolyte for ion conduction between the anode electrode and the cathode electrode inside the battery cell, a housing inside which the anode electrode, the cathode electrode, and the electrolyte are received, and a sensor apparatus that has a reference electrode that is located inside the housing of the battery cell in contact with the electrolyte, and a sensing device for sensing sensor data, the sensing device being located inside the housing, the sensing device having an anode terminal that is electrically connected to the first battery terminal inside the housing, a cathode terminal that is electrically connected to the second battery terminal inside the housing, and a reference terminal that is electrically connected to the reference electrode inside the housing; and

sensing by way of the sensing device, as sensor data, a voltage between the anode electrode and the cathode electrode, a voltage between the reference electrode and the anode electrode, and/or a voltage between the reference electrode and the cathode electrode, in order to monitor the battery cell.

A sensor apparatus recited above can advantageously be utilized or used in connection with the monitoring method. A battery cell recited above can also be advantageously utilized or used in connection with the monitoring method.

Also advantageous is a computer program product having program code that is stored on a machine-readable medium such as a semiconductor memory, a hard-drive memory, or an optical memory, and is used to carry out the aforementioned monitoring method when the program is executed on a computer or an apparatus.

According to embodiments of the present invention, an integrated measurement of electrode potentials of a battery cell, for example of a lithium ion battery cell, is made possible by way of a sensor apparatus inside the battery cell even during operation. What is significant here is that a sensor apparatus or a sensor is or becomes placed inside a hermetic cell housing. This sensor is connected from inside to the battery terminals, which are respectively at the same potential as the anode electrode and at the same potential as the cathode electrode. A third electrode is or becomes brought into ionic contact with the electrolyte in order to serve as a reference electrode. For example, the reference electrode is mounted in the current path between anode and cathode.

An advantage of the present invention is that a separate or mutually independent measurement of the electrode potential of the anode and cathode is enabled. The measured potentials enable an improved identification of the state of charge (SOC) and in particular also the state of health (SOH) of the battery cell. In addition, an advantageously small number of measurements of an idle voltage or open circuit potential (OCP) of the battery cell is needed in order to identify the SOH of the cell. It is thereby possible, based on the sensed state variables of the battery cell, to identify in a reliably and physically compact manner whether the battery cell is reliably operable.

According to an embodiment of the sensor apparatus, the sensing device can be embodied to sense, as the sensor data, a voltage between the anode electrode and the cathode electrode, a voltage between the reference electrode and the anode electrode, and additionally or alternatively a voltage between the reference electrode and the cathode electrode. This makes possible an identification or measurement of an anode potential and a cathode potential with respect to a potential of the reference electrode. The potentials of the anode and cathode can be measured separately from one another, rather than merely the difference thereof between the battery terminals. An embodiment of this kind offers the advantage of enabling a reliable and accurate identification of a charge state or overall state of the battery cell.

The sensing device can also be embodied to sense, as the sensor data, a temperature and/or a pressure of the battery cell. The sensing device can thus be embodied to sense multiple state variables of the battery cell. The sensing device can have at least one sensor element and/or can be embodied to receive sensor data from sensor elements. An embodiment of this kind offers the advantage of enabling an even more exact and more reliable evaluation of the overall state of the battery cell.

The sensing device can furthermore be embodied to modulate the sensed sensor data. The sensing device can also be embodied to output the modulated sensor data to the first battery terminal and additionally or alternatively to the second battery terminal. The sensing device can be embodied to send the sensor data or measured data, for example in the form of a sensor signal, to an external receiver, e.g. a battery management system by modulation over at least one of the battery terminals (“power line communication”). Modulation and output or transfer of the sensor data can occur in carrier-frequency fashion or as modulation of a carrier frequency. The carrier frequency can be imprinted as an electrical voltage or as an electrical current. The sensor data can also be transferred by load modulation. Optionally, the sensing device can have a transmitting device that can be embodied to modulate the sensor data in order to generate a sensor signal, and to output the sensor signal to at least one of the battery terminals. The sensing device or the transmitting device can be embodied, in the context of modulation and output or transfer, to modulate and output or transfer the sensor data in accordance with a definable protocol. The sensing device can also have a receiving device that can be embodied to receive and demodulate a signal from at least one of the battery terminals. An embodiment of this kind offers the advantage that costly additional passthroughs through the hermetic cell housing for additional signal leads can be avoided. Advantageous sensing and transmission of sensor data of the battery cell can thus be carried out by way of the sensor apparatus without negatively affecting a sealing and protective function of the housing of the battery cell. The sensor data can be transferred out of the battery via leads that exist or are provided, so that no additional wiring outlay for signal leads is created. The sensor apparatus, and thus also the battery cell, can furthermore advantageously be integrated into a multi-cell electrical energy reservoir in terms of signal communication, and sensor data can advantageously be transferred via power supply leads.

In particular, the reference electrode can be locatable or located in an ion current path between the anode electrode and the cathode electrode. The reference electrode can have a dimension of less than 100 micrometers, preferably less than 50 micrometers, in a direction transverse to the ion current path. The reference electrode can be placeable or placed so that the reference electrode is in ionic contact with an electrolyte of the battery cell which, in particular, fills pores of the anode electrode, of the cathode electrode, and/or of the separator device. The reference electrode can preferably be located in the path of the current that flows between the anode electrode and the cathode electrode. The reference electrode can be dimensioned so that a current density distribution is not significantly modified during operation of the battery cell. A preferred diameter of the reference electrode is less than 50 micrometers. An embodiment of this kind offers the advantage that a reliable reference potential can be read off at the reference electrode without negatively affecting functioning of the battery cell.

The reference electrode can also be locatable or located at least partly in or on a separator device located between the anode electrode and the cathode electrode. The reference electrode can be locatable or located on a surface of the separator device, or can be receivable or received at least partly in the separator device. The reference electrode can be at least partly protected by the separator device from electrical contact with the anode electrode and/or the cathode electrode; in addition, a further contact protection device separator device can be provided, for example an electrically nonconductive film.

According to an embodiment of the battery cell, the battery cell can have a lithium ion cell having an electrolyte containing lithium ions. The reference electrode of the sensor apparatus can have a lithium-containing material that is capable of reacting with lithium ions of the electrolyte and has a potential that is stable relative to lithium. The sensor apparatus of the battery cell can have a reference electrode that is in ionic contact with the electrolyte of the battery cell. The reference electrode that is electrically connected to the sensing device of the battery cell can have a lithium-containing material that can react faradically with lithium ions in the electrolyte and has a stable potential that does not change with lithium content. The reference electrode can have, for example, Li, LiSn, Li₄Ti₅O₁₂, LiFePO₄, or another reference electrode material having a potential that is stable with respect to lithium metal. An embodiment of this kind offers the advantage that reliable and exact identification of a charge state or overall state of the battery cell is enabled for a common physical form or configuration of a battery cell.

According to an embodiment of the checking method, the method can have a step of modulating the sensed sensor data. The method can also have a step of outputting the modulated sensor data to the first battery terminal and additionally or alternatively to the second battery terminal. The sensor data or measured data can be transmitted, for example in the form of a sensor signal, to an external receiver, e.g. a battery management system, by modulation over at least one of the battery terminals (“power line communication”). Modulation and output or transfer of the sensor data can occur in carrier-frequency fashion or as modulation of a carrier frequency. The carrier frequency can be imprinted as an electrical voltage or as an electrical current. The sensor data can also be transferred by load modulation. Modulation and output or transfer of the sensor data can occur in accordance with a definable protocol. Steps of receiving and demodulating a signal from at least one of the battery terminals can also be provided. An embodiment of this kind offers the advantage that costly additional passthroughs through the hermetic cell housing for additional signal leads can be avoided. Advantageous sensing and transmission of sensor data of the battery cell can thus be carried out by way of the sensor apparatus without negatively affecting a sealing and protective function of the housing of the battery cell. The sensor data can be transferred out of the battery via leads that exist or are provided, so that no additional wiring outlay for signal leads is created. The sensor apparatus, and thus also the battery cell, can furthermore advantageously be integrated into a multi-cell electrical energy reservoir in terms of signal communication, and sensor data can advantageously be transferred via power supply leads.

The sensing device can optionally be embodied to output the sensor data, in particular an information item regarding an electrical potential of the reference electrode, to an evaluation device outside the battery cell. An evaluation device of this kind can be embodied to identify a voltage between the anode electrode and the cathode electrode, a voltage between the reference electrode and the anode electrode, and additionally or alternatively a voltage between the reference electrode and the cathode electrode.

### BRIEF DESCRIPTION OF THE DRAWINGS

FIG. 1 schematically depicts a battery cell and a sensor apparatus according to an exemplifying embodiment of the present invention.

FIG. 2 is a flow chart of a method according to an exemplifying embodiment of the present invention.

FIG. 3 is a flow chart of a method according to an exemplifying embodiment of the present invention.

### DETAILED DESCRIPTION

In the description below of preferred exemplifying embodiments of the present invention, identical or similar reference characters are used for the elements of similar function depicted in the various Figures, and repeated description of the elements is omitted.

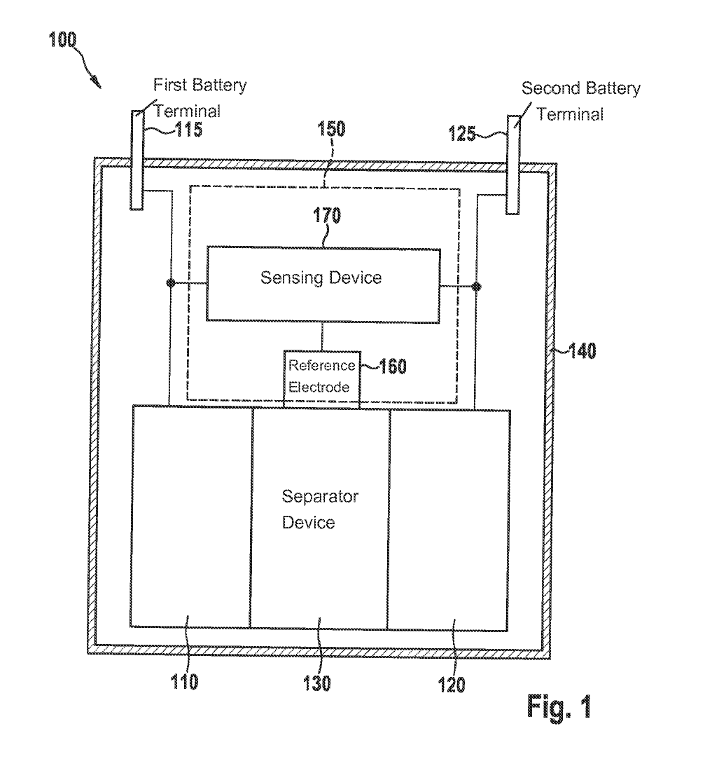

FIG. 1 schematically depicts a battery cell and a sensor apparatus according to an exemplifying embodiment of the present invention. It shows a battery cell 100, an anode electrode 110, a first battery terminal 115, a cathode electrode 120, a second battery terminal 125, a separator device 130, a housing 140, a sensor apparatus 150, a reference electrode 160, and a sensing device 170.

Battery cell 100 has anode electrode 110, first battery terminal 115, cathode electrode 120, second battery terminal 125, separator device 130, and housing 140. Battery cell 100 further has sensor apparatus 150. Sensor apparatus 150 has reference electrode 160 and sensing device 170. Anode electrode 110, an internal segment of first battery terminal 115, cathode electrode 120, an internal segment of second battery terminal 125, separator device 130, and sensor apparatus 150 are located or received inside housing 140 of battery cell 100. A contact segment of first battery terminal 115 and a contact segment of second battery terminal 125 are located on an outer surface of housing 140 or extend from the outer surface of housing 140 outward from housing 140.

According to the exemplifying embodiment of the present invention depicted in FIG. 1, anode electrode 110 is connected to first battery terminal 115 by way of a first electrical connecting lead. In particular, anode electrode 110 is electrically connected to the internal segment of first battery terminal 115. Cathode electrode 120 is also connected to second battery terminal 125 by way of a second electrical connecting lead. In particular, cathode electrode 120 is electrically connected to the internal segment of second battery terminal 125.

Separator device 130 is located between anode electrode 110 and cathode electrode 120. Anode electrode 110, cathode electrode 120, separator device 130, and reference electrode 160 are located in contact with an electrolyte. An ion current can flow between anode electrode 110 and cathode electrode 120 when battery cell 100 is in operation.

Housing 140 of battery cell 100 is embodied to bring about hermetic sealing of anode electrode 110, cathode electrode 120, the connecting leads, separator device 130, and sensor apparatus 150.

Reference electrode 160 of sensor apparatus 150 is located in contact with separator 130. Although this is not explicitly depicted in FIG. 1, reference electrode 160 can extend at least partly into separator device 130, or can be at least partly surrounded by separator device 130. The reference electrode can also be located at a different site inside battery cell 100. Reference electrode 160 is in ionic contact with the electrolyte.

Sensing device 170 of sensor apparatus 150 is embodied to sense sensor data with regard to battery cell 100. Sensing device 170 has an anode terminal, a cathode terminal, and a reference terminal. Reference electrode 160 is electrically connected, for example by way of an electrical lead, to the reference terminal of sensing device 170 inside housing 140. The anode terminal of sensing device 170 is electrically connected to first battery terminal 115 inside housing 140, more precisely to the first connecting lead which creates an electrical connection inside housing 140 between anode electrode 110 and first battery terminal 115 or the internal segment thereof. The cathode terminal of sensing device 170 is electrically connected to second battery terminal 125 inside housing 140, more precisely to the second connecting lead which creates an electrical connection between cathode electrode 120 and second battery terminal 125 or the internal segment thereof.

When battery cell 100 or sensor apparatus 150 is in operation, sensing device 170 is embodied to sense a voltage between anode electrode 110 and cathode electrode 120. Expressed differently, sensing device 170 is embodied to measure a voltage between the anode terminal and cathode terminal of sensing device 170. Sensing device 170 is also embodied to sense a voltage between anode electrode 110 and reference electrode 160. Expressed differently, sensing device is embodied to measure a voltage between the anode terminal and reference terminal of sensing device 170. Sensing device is furthermore embodied to sense a voltage between cathode electrode 120 and reference electrode 160. Expressed differently, sensing device 170 is embodied to measure a voltage between the cathode terminal and reference terminal of sensing device 170.

Sensor apparatus 150 or sensing device 170 can also be embodied to sense at least one further state variable, for example a temperature and/or a pressure in battery cell 100, as the sensor data. Sensor apparatus 150 or sensing device 170 can furthermore also be embodied to modulate the sensed sensor data that encompass at least one of the voltages, and to output the modulated sensor data to first battery terminal 115 and/or to second battery terminal 125. The sensor data can thus be transferred to an apparatus located outside the battery cell.

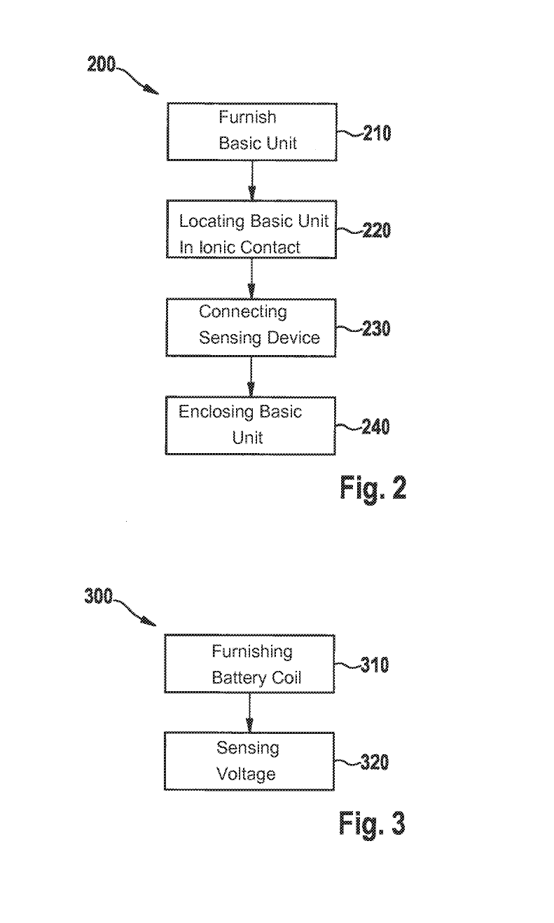

FIG. 2 is a flow chart of a method 200 for manufacturing a battery cell of an electrical energy reservoir according to an exemplifying embodiment of the present invention.

Method 200 has a step of furnishing 210 a basic unit of the battery cell, a reference electrode, and a sensing device for sensing sensor data. The basic unit has an anode electrode electrically connected to a first battery terminal, a cathode electrode electrically connected to a second battery terminal, and an electrolyte for ion conduction between the anode electrode and cathode electrode.

Method 200 furthermore has a step of locating 220 the reference electrode in ionic contact with the electrolyte.

Method 200 also has a step of connecting 230 the sensing device. In the connecting step 230, an anode terminal of the device is electrically connected to the first battery terminal, a cathode terminal of the device is electrically connected to the second battery terminal, and a reference terminal of the device is electrically connected to the reference electrode.

Method 200 furthermore has a step of enclosing 240 the basic unit, the reference electrode, and the sensing device by way of housing. Only the first battery terminal and second battery terminal are guided out of the housing.

The battery cell having the sensor apparatus of FIG. 1, for example, can advantageously be manufactured using method 200.

FIG. 3 is a flow chart of a method 300 for monitoring a battery cell of an electrical energy reservoir according to an exemplifying embodiment of the present invention.

Method 300 has a step of furnishing 310 a battery cell. The battery cell has an anode electrode that is electrically connected to a first battery terminal of the battery cell, a cathode electrode that is electrically connected to a second battery terminal of the battery cell, an electrolyte for ion conduction between the anode electrode and cathode electrode inside the battery cell, a housing inside which the anode electrode, the cathode electrode, and the electrolyte are received, and a sensor apparatus. The sensor apparatus has a reference electrode that is located inside the housing of the battery cell in contact with the electrolyte, and a sensing device for sensing sensor data. The sensing device is located inside the housing. The sensing device has an anode terminal that is electrically connected to the first battery terminal inside the housing, a cathode terminal that is electrically connected to the second battery terminal inside the housing, and a reference terminal that is electrically connected to the reference electrode inside the housing.

Method 300 also has a step of sensing 320 by way of the sensing device, as sensor data, a voltage between the anode electrode and the cathode electrode, a voltage between the reference electrode and the anode electrode, and additionally or alternatively a voltage between the reference electrode and the cathode electrode, in order to monitor the battery cell.

The method can advantageously be performed in connection with the sensor apparatus or battery cell of FIG. 1.

The exemplifying embodiments described and shown in the Figures are selected only by way of example, Different exemplifying embodiments can be combined with one another entirely or with reference to individual features. An exemplifying embodiment can also be supplemented with features of a further exemplifying embodiment. Method steps according to the present invention can furthermore be performed repeatedly and in a sequence other than the one described.

1.-11. (canceled)

12. A sensor apparatus for a battery cell of an electrical energy reservoir, the battery cell having a housing inside of which are one of receivable and received an anode electrode electrically connected to a first battery terminal, a cathode electrode electrically connected to a second battery terminal, and an electrolyte for ion conduction between the anode electrode and the cathode electrode, the sensor apparatus comprising:
a reference electrode that is one of locatable and located inside the housing of the battery cell in ionic contact with the electrolyte; and
a sensing device for sensing sensor data, the sensing device being one of locatable and located inside the housing, wherein the sensing device includes:
an anode terminal that is one of electrically connectable and electrically connected to the first battery terminal inside the housing,
a cathode terminal that is one of electrically connectable and electrically connected to the second battery terminal inside the housing, and
a reference terminal that is one of electrically connectable and electrically connected to the reference electrode inside the housing.

13. The sensor apparatus as recited in claim 12, wherein the sensing device senses, as the sensor data, at least one of:
a voltage between the anode electrode and the cathode electrode,
a voltage between the reference electrode and the anode electrode, and
a voltage between the reference electrode and the cathode electrode.

14. The sensor apparatus as recited in claim 12, wherein the sensing device senses, as the sensor data, at least one of a temperature and a pressure of the battery cell.

15. The sensor apparatus as recited in claim 12, wherein the sensing device modulates the sensed sensor data and outputs the modulated sensor data to at least one of the first battery terminal and the second battery terminal.

16. The sensor apparatus as recited in claim 12, wherein:
the reference electrode is one of locatable and located in an ion current path between the anode electrode and the cathode electrode, and
the reference electrode has a dimension of less than 100 micrometers in a direction transverse to the ion current path.

17. The sensor apparatus as recited in claim 16, wherein the dimension is less than 50 micrometers.

18. The sensor apparatus as recited in claim 12, further comprising a separator device located between the anode electrode and the cathode electrode, wherein the reference electrode is one of locatable and located at least partly one of in and on the separator device.

19. A battery cell for an electrical energy reservoir, comprising:
an anode electrode that is one of electrically connectable and electrically connected to a first battery terminal of the battery cell;
a cathode electrode that is one of electrically connectable and electrically connected to a second battery terminal of the battery cell;
an electrolyte for ion conduction between the anode electrode and the cathode electrode inside the battery cell;
a housing inside of which the anode electrode, the cathode electrode, and the electrolyte are one of receivable and received; and
a sensor apparatus that is one of locatable and located inside the housing of the battery cell, the sensor apparatus including:
a reference electrode that is one of locatable and located inside the housing of the battery cell in ionic contact with the electrolyte, and
a sensing device for sensing sensor data, the sensing device being one of locatable and located inside the housing, wherein the sensing device includes:
an anode terminal that is one of electrically connectable and electrically connected to the first battery terminal inside the housing,
a cathode terminal that is one of electrically connectable and electrically connected to the second battery terminal inside the housing, and
a reference terminal that is one of electrically connectable and electrically connected to the reference electrode inside the housing.

20. The battery cell as recited in claim 19, further comprising a lithium ion cell having an electrolyte containing lithium ions, wherein the reference electrode of the sensor apparatus includes a lithium-containing material that is capable of reacting with the lithium ions of the electrolyte and that has a potential that is stable relative to lithium.

21. A method for manufacturing a battery cell of an electrical energy reservoir, the method comprising:
furnishing a basic unit of the battery cell, the basic unit having an anode electrode electrically connected to a first battery terminal, a cathode electrode electrically connected to a second battery terminal, an electrolyte for ion conduction between the anode electrode and the cathode electrode, a reference electrode, and a sensing device for sensing sensor data;
locating the reference electrode in ionic contact with the electrolyte;
connecting the sensing device, an anode terminal of the sensing device being electrically connected to the first battery terminal, a cathode terminal of the sensing device being electrically connected to the second battery terminal, and a reference terminal of the sensing device being electrically connected to the reference electrode; and
enclosing the basic unit, the reference electrode, and the sensing device using a housing, only the first battery terminal and the second battery terminal being guided out of the housing.

22. A method for monitoring a battery cell of an electrical energy reservoir, the method comprising:
furnishing a battery cell that has an anode electrode electrically connected to a first battery terminal of the battery cell, a cathode electrode that is electrically connected to a second battery terminal of the battery cell, an electrolyte for ion conduction between the anode electrode and the cathode electrode inside the battery cell, a housing inside of which the anode electrode, the cathode electrode, and the electrolyte are received, and a sensor apparatus that has a reference electrode that is located inside the housing of the battery cell in contact with the electrolyte, and a sensing device for sensing sensor data, the sensing device being located inside the housing, the sensing device having an anode terminal that is electrically connected to the first battery terminal inside the housing, a cathode terminal that is electrically connected to the second battery terminal inside the housing, and a reference terminal that is electrically connected to the reference electrode inside the housing; and
sensing by way of the sensing device, as sensor data, at least one of:
a voltage between the anode electrode and the cathode electrode,
a voltage between the reference electrode and the anode electrode, and
a voltage between the reference electrode and the cathode electrode, in order to monitor the battery cell.

23. The method as recited in claim 22, further comprising:
modulating the sensed sensor data; and
outputting the modulated sensor data to at least one of the first battery terminal and the second battery terminal.
